(19) United States
(12) Patent Application Publication
(10) Pub. No.: US 2007/0091335 A1
(43) Pub. Date: Apr. 26, 2007

(54) Gamut boundary mapping

(76) Inventors: Mark Q. Shaw, Meridian, ID (US); Huanzhao Zeng, Vancouver, WA (US); Di-Yuan Tzeng, Eagle, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/254,378

(22) Filed: Oct. 20, 2005

(51) Int. Cl. G03F 3/08

(52) U.S. Cl. 358/1.9; 358/518

(57) ABSTRACT

Methods, computer readable media, application specific integrated circuits (ASICs) and computing devices including program instructions are provided for gamut boundary mapping. One method embodiment includes defining a region of interest inside a color exchange space by a region boundary, which is formed, at least in part, by a gamut boundary for an output device and an inflated gamut boundary. The method also includes providing a table for converting data from the color exchange space to a physical color space for the output device. In this method, at least a portion of the table is generated by using a first set of nodes sampled inside the gamut boundary and a second set of nodes sampled inside the region of interest and clipped to the inflated gamut boundary.

### BACKGROUND

In the field of color science, it is useful to generate a table for converting data in a color exchange space to device values in a physical color space. This table contains data, which describes a physical color space for a particular output device. Program instructions can execute to use a table to map mathematical expressions that represent colors independent of any device to device values that represent colors for a particular output device. An output device can use such device values to produce color images. Program instructions can also execute to generate the above described table for a particular output device.

To generate a table, program instructions can execute to perform a minimum delta E clipping method to clip sampled nodes that are out of a color gamut of an output device to locations on a gamut boundary of the output device. The clipping of these sampled nodes to locations on the gamut boundary can affect the mapping of data to device values, which can affect colors produced by an output device. A minimum delta E clipping method can generate a table that maps data to device values so that an output device produces color images that do not use the full extent of available colors within its color gamut and/or that unevenly use colors near its gamut boundary.

### BRIEF DESCRIPTION OF THE DRAWINGS

FIG. 1 illustrates an example of an output device suitable to produce a color image, according to embodiments of the present disclosure.

FIG. 2 illustrates a chromaticity graph showing an inflated gamut boundary, according to embodiments of the present disclosure.

FIG. 3 illustrates the graph of FIG. 2, showing nodes clipped to an inflated gamut boundary, according to embodiments of the present disclosure.

FIG. 4 illustrates a graph showing encoded device values that are scaled and offset, according to embodiments of the present disclosure.

FIG. 5A illustrates a portion of a chromaticity graph, showing an example of mapped device values.

FIG. 5B illustrates a portion of a chromaticity graph, showing mapped device values, according to embodiments of the present disclosure.

FIG. 6A illustrates a three-dimensional picture showing an example of converted device values in a physical color space for a device.

FIG. 6B illustrates a three-dimensional picture showing converted device values in a physical color space for a device, according to embodiments of the present disclosure.

### DETAILED DESCRIPTION

Embodiments of the present disclosure include methods, computer readable media, application specific integrated circuits (ASICs) and computing devices including program instructions that are provided for gamut boundary mapping. One method embodiment includes defining a region of interest inside a color exchange space by a region boundary, which is formed, at least in part, by a gamut boundary for an output device and an inflated gamut boundary. The method also includes providing a table for converting data from the color exchange space to a physical color space for the output device. In this method, at least a portion of the table is generated by using a first set of nodes sampled inside the gamut boundary and a second set of nodes sampled inside the region of interest and clipped to the inflated gamut boundary. Embodiments of the present disclosure will now be described in relation to accompanying drawings, which will assist in illustrating the various features of the various embodiments.

An output device has its own color gamut, which has a limit marked by a gamut boundary. An output device can use device values to produce color images using colors within its color gamut (i.e. inside its gamut boundary). However, an output device cannot produce colors out of its color gamut (i.e. outside of its gamut boundary). According to various embodiments of the present disclosure, program instructions can execute to perform an inflated gamut clipping method. An inflated gamut clipping method can generate at least a portion of a table that maps data to device values so that an output device puts out color images that use available colors within its color gamut and that evenly use colors near its gamut boundary.

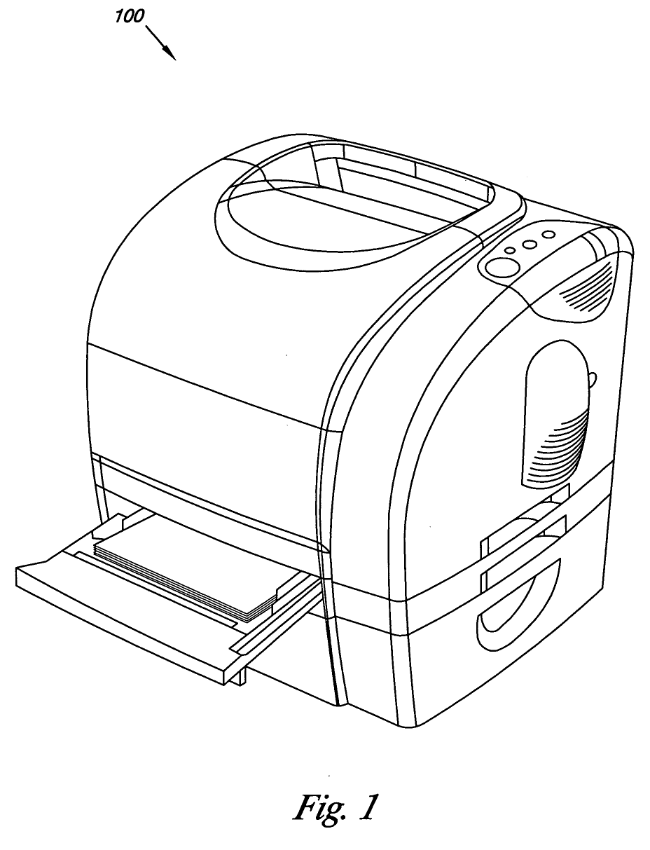

FIG. 1 illustrates an example of an output device suitable to produce a color image, according to embodiments of the present disclosure. FIG. 1 illustrates a printing device 100, which can use device values to print color images, including color characters, on media, such as paper. In various embodiments, a printing device can print on media by firing ink jets and/or by using toner and a laser. Different embodiments of printers, including ink jet and laser printers, can print color images and/or color characters. The printing device 100 has a color gamut and can use device values to produce color images using colors within its color gamut. However, the printing device 100 cannot produce colors out of its color gamut. In another embodiment of the present disclosure, an output device can be a graphic display device, such as a screen, a monitor, a projector, a television, or some other kind of display.

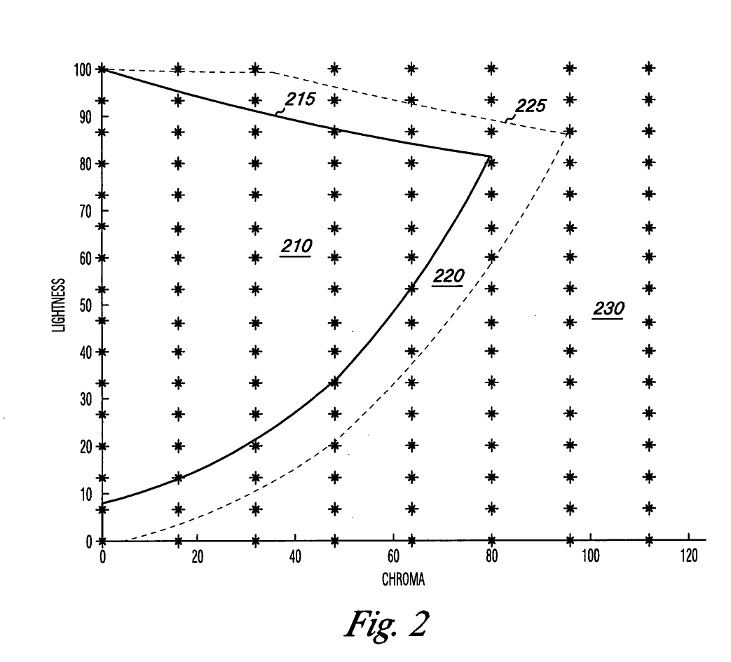

FIGS. 2-6 illustrate embodiments of methods of the present disclosure. Unless explicitly stated, the method embodiments described herein are not constrained to a particular order or sequence. Additionally, some of the described method embodiments or elements thereof can occur or be performed at the same point in time.

The embodiments described herein can be performed by software and/or firmware (i.e., computer executable instructions), hardware, application modules, and the like, executable and/or resident on systems, ASICs, and devices shown herein or otherwise. The embodiments of the invention are not limited to any particular operating environment or to instructions written in a particular programming language. Software, firmware, and/or processing modules, suitable for carrying out embodiments of the present invention, can be resident in one or more devices or locations. Processing modules can include separate modules connected together or include several modules on an application specific integrated circuit (ASIC).

FIG. 2 illustrates a chromaticity graph showing an inflated gamut boundary, according to embodiments of the present disclosure. The graph of FIG. 2 shows a color exchange space. In a color exchange space, data represent colors with mathematical expressions that are independent of any device. A computing device can use such data in color exchange space. For example, one computing device can exchange data in color exchange space with another computing device, so both computing devices understand colors in the same way. One color exchange space is the Commission International de l'Eclairage (CIE) XYZ space (CIEXYZ). Another color exchange space is the CIE L*a*b* space (CIELAB). Other color exchange spaces include colorimetric RGB and other colorimetric spaces. FIG. 2 shows a graph of lightness and chroma at a particular hue angle in CIELAB.

The graph of FIG. 2 shows sampled nodes in CIELAB. Each sampled node is represented by a star. The sampled nodes of FIG. 2 form a regularly spaced grid of sampled nodes. Such sampled nodes can be used in converting data in a color exchange space to device values in a physical color space, as will be understood by one of ordinary skill in the art. In one embodiment, this converting can be accomplished by program instructions that can execute to sample nodes and to use those sampled nodes to generate a table for converting data (e.g. a look-up-table or a BtoA table). Program instructions can execute to use such a table to process data to form device values.

The graph of FIG. 2 also shows references to a particular output device. In the graph of FIG. 2, the particular output device has a gamut boundary 215 at the particular hue angle shown. One end of the gamut boundary 215 begins at a chroma value of zero and a lightness value of 100. The gamut boundary 215 continues from that one end down and to the right, to a cusp, at which the gamut boundary 215 angles sharply. From the cusp, the gamut boundary 215 continues down and to the left until it intersects the lightness axis. From the intersection with the lightness axis, the gamut boundary 215 follows the lightness axis down to another end at a lightness value of zero. Various output devices can have various gamut boundaries, depending on capabilities of the devices and characteristics of color hues, among other factors. The values in FIG. 2 are shown by way of example and are not intended to limit a gamut boundary to any particular size or shape.

The graph of FIG. 2 also shows an inflated gamut boundary 225, based upon the gamut boundary 215. The inflated gamut 225 boundary is similar in shape to the gamut boundary 215 and larger in size than the gamut boundary 215. In the embodiment shown in FIG. 2, the inflated gamut boundary 225 is scaled up from and offset from the gamut boundary 215. In various embodiments, an inflated gamut boundary can be defined mathematically or derived empirically.

One end of the inflated gamut boundary 225 begins at a chroma value of zero and a lightness value of 100. The inflated gamut boundary 225 continues from that one end down and to the right, first gradually, then more steeply, to a cusp, at which the inflated gamut boundary 225 angles sharply. From the cusp, the inflated gamut boundary 225 continues down and to the left until it intersects the chroma axis. From the intersection with the chroma axis, the inflated gamut boundary 225 follows the chroma axis to the left to another end at a chroma value of zero. The inflated gamut boundary 225 of FIG. 2 is shown by way of example and is not intended to limit an inflated gamut boundary to any particular size or shape.

In FIG. 2, the gamut boundary 215 and the inflated gamut boundary 225 define different areas in the chromaticity graph. The area inside the gamut boundary is a color gamut 210 of the particular output device. The area outside the inflated gamut boundary 225 is an outside area 230. The area between the gamut boundary 215 and the inflated gamut boundary 225 is a region of interest 220. The gamut boundary 215 and the inflated gamut boundary 225 form a region boundary, which defines the region of interest 220. Program instructions can execute to define a region boundary, as described herein.

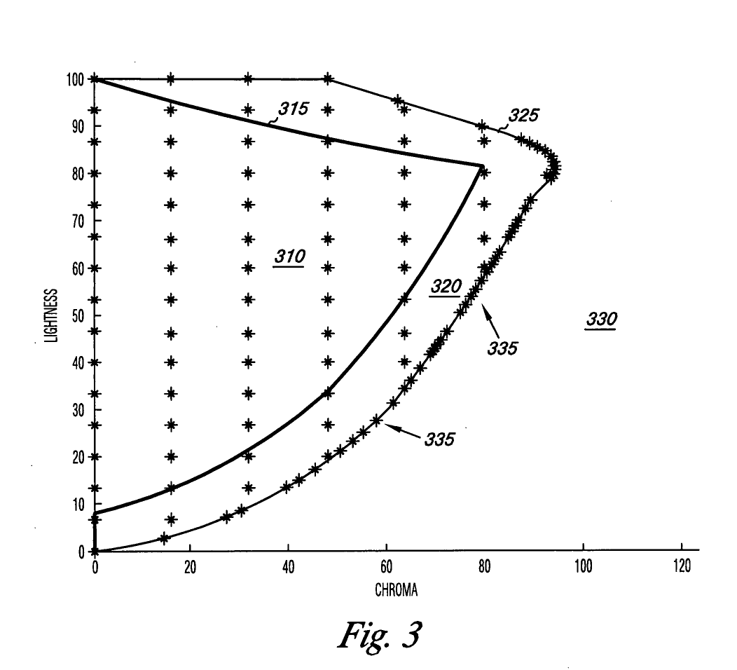

As shown in FIG. 2, different sampled nodes are in different areas in the chromaticity graph. The presence or absence of sampled nodes in these different areas can affect program instructions that can execute to generate a table for converting data in CIELAB to device values in the physical color space for the particular output device, according to the present disclosure. Thus, the definition of the inflated gamut boundary 225 can affect this conversion of data, as described in FIG. 3.

FIG. 3 illustrates the graph of FIG. 2, showing nodes clipped to an inflated gamut boundary, according to embodiments of the present disclosure. In FIG. 3, as in FIG. 2, a gamut boundary 315 for a particular output device and an inflated gamut boundary 325 define a color gamut 310, a region of interest 320, and an outside area 330. In FIG. 3, as in FIG. 2, stars represent sampled nodes in CIELAB.

However, some of the sampled nodes in FIG. 3 differ from the sampled nodes in FIG. 2. In FIG. 3, the sampled nodes inside the color gamut 310 and inside the region of interest 320 are the same as the sampled nodes inside the color gamut 210 and the region of interest 220 of FIG. 2. The regularly sampled nodes that are shown in the outside area 230 of FIG. 2 are clipped to the inflated gamut boundary 325, in FIG. 3, to form clipped nodes 335. Program instructions can execute to clip sampled nodes to form the clipped nodes 335, as shown in FIG. 3. In various embodiments, program instructions can execute to perform various clipping methods, as will be understood by those of ordinary skill in the art, to form the clipped nodes 335. For example, program instructions can execute to perform straight clipping, closest LAB clipping, node clipping, cusp clipping, or some other kind of clipping, to form the clipped nodes 335. The locations of the clipped nodes 335 on the inflated gamut boundary 325 are shown by way of example and are not intended to limit clipping to any particular method.

Sampled nodes can be used to generate a table for converting data from a color exchange space to a physical color space for an output device, as will be understood by those of ordinary skill in the art. Program instructions can execute to regularly sample nodes in a color exchange space and to define a color exchange space location for each sampled node. Program instructions can also execute to clip some of the sampled nodes, to various locations in the color exchange space. Program instructions can execute to associate one or more device values with each node. Program instructions can execute to use the device values associated with the nodes to generate the table.

This table can be used for converting data from the color exchange space to the physical color space for the device, as will be understood by those of ordinary skill in the art. Program instructions can execute to process data in the color exchange space, through the table to form device values. Program instructions can execute to use the color exchange space locations to identify one or more sampled nodes located near each point of data in the color exchange space. Program instructions can execute an interpolation algorithm for each data point, by using the device values associated with the sampled node(s) identified near the data point, to map device values for each data point. By repeating this process for multiple data points, data can be converted from the color exchange space to the physical color space for the output device.

According to the present disclosure, determining which sampled nodes are clipped affects how device values are mapped, which will affect how a color is produced. In various embodiments, nodes sampled inside a region of interest are clipped to an inflated gamut boundary. In one embodiment, a region of interest can be defined by a particular region boundary that encloses sampled nodes, as described in FIG. 2. In this embodiment, the region boundary is formed, at least in part, by a gamut boundary for the output device and an inflated gamut boundary. In various embodiments, the region boundary can also be formed, in part, by other lines and/or curves. Program instructions can execute to define a region of interest by defining a region boundary, as described in this embodiment.

In another embodiment, a region of interest can be defined by describing particular nodes included in the region. A region of interest can include less than all sampled nodes outside a gamut boundary. For example, program instructions can execute so that a region of interest does not include sampled nodes that are relatively far from a gamut boundary. This can limit how many sampled nodes are clipped, which can limit how much out-of-gamut data is mapped to device values near the gamut boundary.

A region of interest can also include sampled nodes used by a table for converting data inside the gamut boundary from the color exchange space to a physical color space for the device. For example, program instructions can execute so that a region of interest includes sampled nodes outside a gamut boundary that are identified as near in-gamut data points and used for interpolating device values for those data points. This can target which sample nodes are clipped, which can increase clipping effects on out-of-gamut data that are mapped to device values near the gamut boundary.

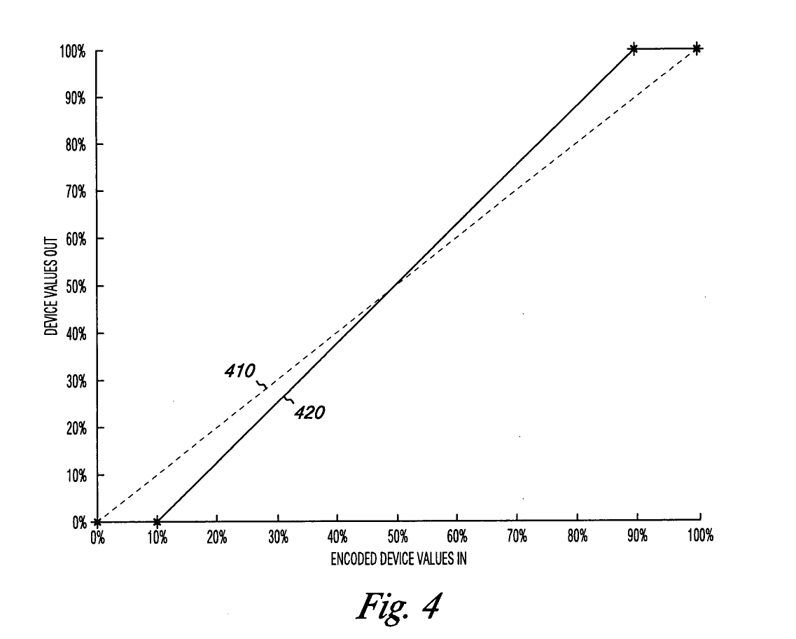

FIG. 4 illustrates a graph showing encoded device values that are scaled and offset, according to embodiments of the present disclosure. Encoded device values are encoded in a table for converting data in a color exchange space to device values in a physical color space, as will be understood by one of ordinary skill in the art. FIG. 4 shows identity encoded device values 410 and scaled and offset encoded device values 420. The identity encoded device values 410 represent data inside a gamut boundary. The identity encoded device values 410 are shown as a straight line for illustrative purposes only. In various embodiments, identity encoded device values can be nonlinear and can be represented by lines, curves, patterns, and/or irregular data points. The scaled and offset encoded device values 420 represent device values formed by scaling and offsetting the identity encoded device values 410.

Different scaling techniques can obtain different results, in various embodiments of the present disclosure. Scaling can be applied to modify one or more values or to modify a set of values. In one embodiment, scaling can compress a set of values to occupy a narrower range of values. For example, program instructions can multiply each value in a set of values by a scale factor less than one, to compress the set of values to occupy a narrower range. In another embodiment, scaling can expand a set of values to occupy a broader range of values. For example, program instructions can multiply each value in a set of values by a scale factor greater than one, to expand the set of values to occupy a broader range. In other embodiments, scaling can be accomplished by program instructions that can execute various algorithms to scale original values so that the scaled values occupy a range of a different size than a range that the original values occupied.

Different offsetting techniques can also obtain different results, in various embodiments of the present disclosure. Offsetting can be applied to modify one or more values or to modify a set of values. In one embodiment, offsetting can move a set of values to occupy a higher range of values. For example, program instructions can add a particular amount to each value in a set of values, to move the set of values to occupy a higher range. In another embodiment, offsetting can move a set of values to occupy a lower range of values. For example, program instructions can subtract a particular amount to each value in a set of values, to move the set of values to occupy a lower range. In other embodiments, offsetting can be accomplished by program instructions that can execute various algorithms to offset original values so that the offset values occupy a range of a different location than a range that the original values occupied.

In various embodiments, different channels of an output device can have different scaling and/or offsetting. As an example, for an output device with red, green, and blue output channels, program instructions can execute to scale and offset a red channel one way, and scale and offset a green channel another way. Program instructions can execute to perform different scaling and/or offsetting for different channels of an output device.

As shown in FIG. 4, the scaled and offset encoded device values 420 are formed by scaling and offsetting the identity encoded device values 410. The identity encoded values 410 occupy a range from 0% to 100%. In the embodiment of FIG. 4, to scale the identity encoded device values 410, each value in the identity encoded device values 410 is multiplied by a scale factor of 0.8 so the values occupy a narrower range of 80%. To offset the identity encoded device values 410, an amount equal to 10% is added to the scaled values so the values occupy a higher range from 10% to 90%. This offset centers the scaled and offset encoded device values 420 on a center of the identity encoded device values 410. The scaling and offsetting in FIG. 4 are shown by way of example and are not intended to limit the scaling and offsetting of values to any particular size or location.

Scaling, offsetting, or a combination of scaling and offsetting of encoded device values can improve interpolation through a table for converting data from a color exchange space to a device values in a physical color space for an output device. As one example, program instructions can execute to scale a range of encoded device values, so that the range is resized and the scaled range does not occupy a portion of color encoding in a table for converting data in a color exchange space to device values in a physical color space. As another example, program instructions can execute to offset a range of encoded device values, so that the range is relocated and the offset range does not occupy a portion of color encoding.

Such unoccupied portions of color encoding are available for other encoded device values. In FIG. 4, the scaled and offset encoded device values 420, do not occupy two portions of color encoding. In the embodiment of FIG. 4, a portion of color encoding represented by 0% to 10% and a portion of color encoding represented by 90% to 100% are available portions since they are unoccupied by the scaled and offset encoded device values 420. These examples of available portions are available for other encoded device values, such as modified encoded values formed from out-of-gamut device values, as described herein.

When converting data from a color exchange space to device values in a physical color space, as described herein, some data can be converted to out-of-gamut device values (i.e. device values that are outside of a gamut boundary for an output device). An output device can use device values within its color gamut to produce color images, however, an output device cannot produce colors out of its color gamut. In color exchange space, a color gamut has a limit marked by a gamut boundary. In physical color space, a color gamut has limits marked by a minimum device value and a maximum device value. An output device can use device values that are greater than or equal to its minimum device value to produce color images. An output device can also use device values that are less than or equal to its maximum device value to produce color images. Device values less than a minimum device value for an output device or greater than a maximum device value for the output device are out-of-gamut device values for the output device.

As an example of color gamut limits in a physical color space, an output device with a physical color space that uses an eight-bit color system can have a minimum device value of zero and a maximum device value of 255. This output device can use values from zero through 255 to produce colors. In this example, device values that are less than zero or greater than 255 are out-of-gamut device values for the output device.

Out-of-gamut device values can be modified to form modified encoded device values. Device values that are less than a minimum device value, can be modified to form modified encoded device values that are greater than or equal to a minimum device value and within an available portion. For example, if a minimum device value is zero, program instructions can execute to offset a device value of minus ten to form a modified encoded device value of positive ten. Similarly, device values that are greater than a maximum device value, can be modified to form modified encoded device values that are less than or equal to a maximum device value and within an available portion. For example, if a maximum device value is 255, program instructions can execute to scale a device value of 270 by a factor of 0.9 to form a modified encoded device value of 243. Thus, out-of-gamut device values can be modified to form modified encoded device values.

In various embodiments of the present disclosure, out-of-gamut device values can be modified to form modified encoded device values within an available portion of a color gamut created by scaling and/or offsetting converted in-gamut device values. For example, program instructions can execute to modify out-of-gamut device values, as described herein, to form modified encoded device values within an available portion of a color gamut.

Scaling and/or offsetting can create an available portion of an appropriate size in color encoding, to accommodate modified encoded device values formed by modifying out-of-gamut device values for a particular device. As one example, if relatively few modified encoded device values are formed from a particular device, program instructions can execute to scale in-gamut device values to a broader range of values, creating a smaller available portion in a color gamut, appropriate for fewer modified encoded device values. As another example, if relatively many modified encoded device values are formed from a particular device, program instructions can execute to scale in-gamut device values to a narrower range of values, creating a larger available portion in a color gamut, appropriate for many modified encoded device values. As will be understood by those of ordinary skill in the art, scaling and/or offsetting can also create an available portion in an appropriate location in a color gamut, to accommodate modified encoded device values within the gamut.

Various other embodiments of the present disclosure can be implemented, as will be understood by those of ordinary skill in the art. In one embodiment, data that are converted from a color exchange space to a physical color space, as described herein, can be processed through one dimensional look-up-tables to form device values within a color gamut for an output device. In another embodiment, data in the form of an ICC profile can be converted from color exchange space to a physical color space for a device, as described herein, by using output shapers.

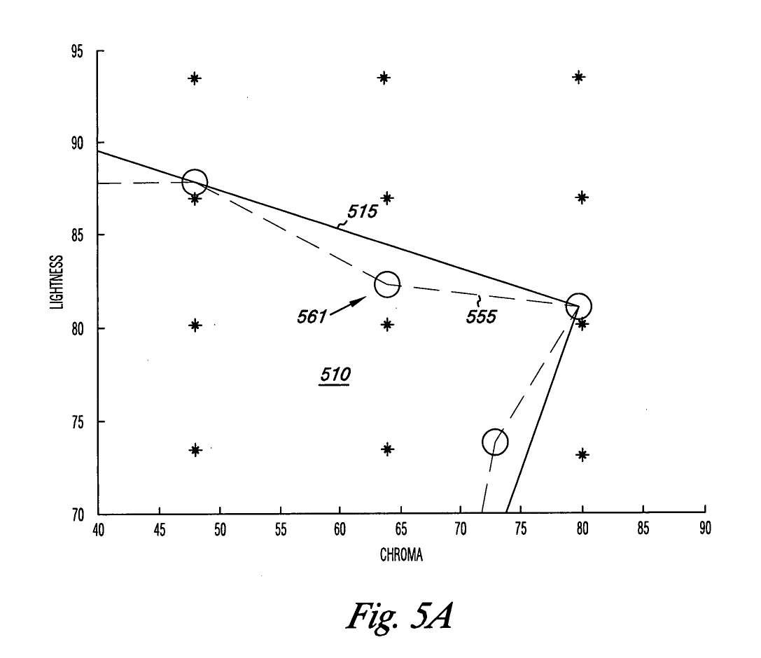

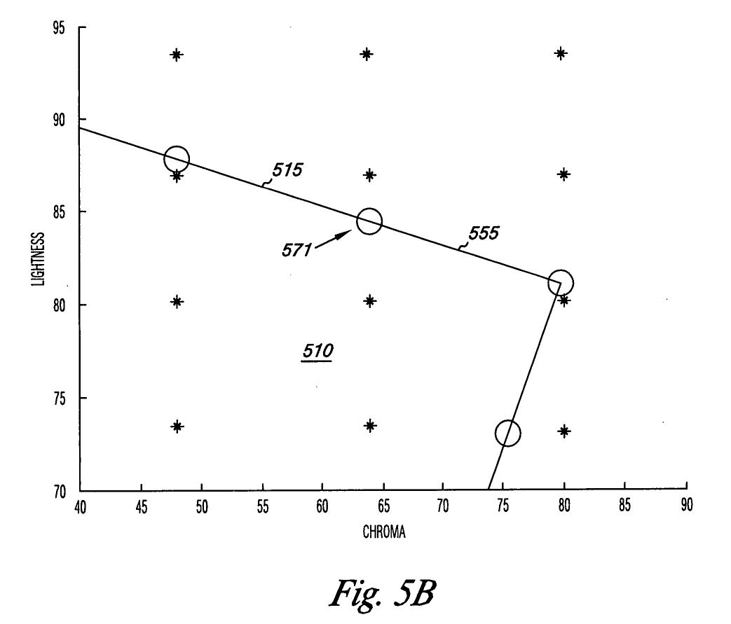

FIG. 5A illustrates a portion of a chromaticity graph, showing an example of mapped device values. In FIG. 5A, a gamut boundary 515 for a particular output device defines a color gamut 510, and stars represent sampled nodes in CIELAB. Also in FIG. 5A, circles, such as circle 561, represent mapped device values, which are connected by reference line 555. The device values in FIG. 5A represent data mapped by a table generated by using a clipping method, in which sampled nodes are clipped to the gamut boundary 515. In the example of FIG. 5A, the device values do not fall on the gamut boundary 515, representing colors that do not use the full extent of available colors within the color gamut 510, and the locations of the device values form an irregular shape, representing uneven coloring near the gamut boundary 515. FIG. 5A is provided solely as an example for comparison with FIG. 5B.

FIG. 5B illustrates a portion of a chromaticity graph, showing mapped device values, according to embodiments of the present disclosure. In FIG. 5B, a gamut boundary 515 for a particular output device defines a color gamut 510, and stars represent sampled nodes in CIELAB. Also in FIG. 5B, circles, such as circle 571, represent mapped device values, which are connected by reference line 555. Reference line 555 coincides with gamut boundary 515, and thus is not visually separable. The device values in FIG. 5B represent data mapped by a table generated by using a clipping method, in which sampled nodes are clipped to an inflated gamut boundary. In the example of FIG. 5B, the device values fall on the gamut boundary 515, representing colors that use the full extent of available colors within the color gamut 510, and the locations of the device values form a smooth reference line 555, representing even coloring on the gamut boundary 515. The locations of the mapped device values in FIG. 5A are shown for illustrative purposes only.

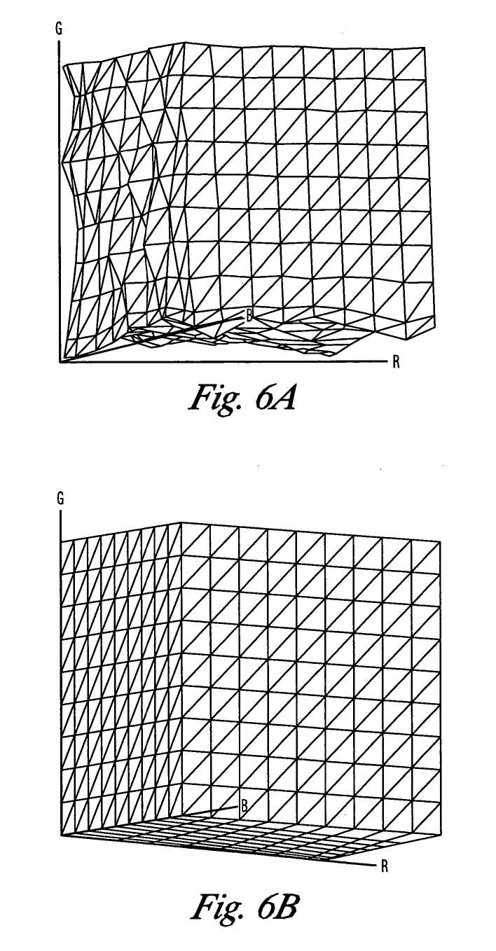

FIG. 6A illustrates a three-dimensional picture showing an example of converted device values in a physical color space for a device. As shown in FIG. 6A, the physical color space is a Red-Green-Blue (RGB) color space with Red, Blue, and Green axes represented by R, B, and G respectively. The device values in FIG. 6A represent data converted from a color exchange space by using a table generated by using a clipping method, in which sampled nodes are clipped to a gamut boundary. In the example of FIG. 6A, cube edges do not meet the Red, Green, and Blue, representing colors that do not use an available gamut, and rough cube faces represent uneven colors. FIG. 6A is provided solely as an example for comparison with FIG. 6B.

FIG. 6B illustrates a three-dimensional picture showing converted device values in a physical color space for a device, according to embodiments of the present disclosure. As in FIG. 6A, the physical color space is an RGB color space with Red, Blue, and Green axes. The device values in FIG. 6B represent data converted from a color exchange space by using a table generated, at least in part, by using an inflated gamut clipping method, in which sampled nodes are clipped to an inflated gamut boundary, as described herein.

An output device can use the device values represented in FIG. 6B to produce a color. The output device can use the device values shown to produce a color that uses available colors within a color gamut of the output device. This use of available colors is represented in FIG. 6B by cube edges that meet the Red, Green, and Blue axes. The output device can also use the device values shown to produce a color that evenly uses colors near a gamut boundary of the color gamut. This even use of colors is represented in FIG. 6B by smooth cube faces on three planes: a plane defined by the Green axis and the Blue axis, a plane defined by the Blue axis and the Red axis, and a plane defined by the Green axis and the Red axis (plane not visible in FIG. 6B).

Although specific embodiments have been illustrated and described herein, those of ordinary skill in the art will appreciate that an arrangement calculated to achieve the same techniques can be substituted for the specific embodiments shown. This disclosure is intended to cover all adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the embodiments of the present disclosure require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed:

1. A method for converting data from a color exchange space to a physical color space for an output device, comprising:
defining a region of interest inside the color exchange space by a region boundary, which is formed, at least in part, by a gamut boundary for the output device and an inflated gamut boundary; and
providing a table for converting data from the color exchange space to the physical color space for the output device, wherein at least a portion of the table is generated by using nodes sampled inside the region of interest and clipped to the inflated gamut boundary.

2. The method of claim 1, wherein the method includes converting data inside the gamut boundary from the color exchange space to the physical color space for the output device by using the table to process the data inside the gamut boundary to form a first set of encoded device values.

3. The method of claim 2, wherein the method includes converting data inside the region of interest from the color exchange space to the physical color space for the output device by using the table to process the data inside the region of interest, to form a second set of encoded device values.

4. The method of claim 3, wherein the method includes:
creating an available portion within color encoding in the table, by scaling and offsetting the first set of device values; and
modifying out-of-gamut device values of the second set to form modified encoded device values within the available portion.

5. The method of claim 4, wherein
the scaling includes multiplying the first set of device values by a scale factor to form a scaled range; and
the offsetting includes centering the scaled range on a center of the first set of device values.

6. The method of claim 3, wherein the method includes:
creating an available portion within the color encoding, at least in part, by offsetting the first set of device values; and
modifying out-of-gamut device values of the second set to form modified device values within the available portion.

7. The method of claim 3, wherein the method includes:
creating an available portion within the color encoding, at least in part, by scaling the first set of device values; and
modifying out-of-gamut device values of the second set to form modified device values within the available portion.

8. The method of claim 6, wherein modifying out-of-gamut device values includes scaling device values of the second set that are greater than a maximum device value and offsetting device values of the second set that are less than a minimum device value, to form modified device values that are greater than or equal to the minimum device value, less than or equal to the maximum device value, and within the available portion.

9. A computer readable medium having instructions for causing a device to perform a method, comprising:
sampling a color exchange space, which includes a gamut boundary for an output device, to obtain sampled nodes; and
defining a region of interest, which lies outside the gamut boundary, wherein the region includes:
less than all sampled nodes outside the gamut boundary; and
sampled nodes used by a table for converting data inside the gamut boundary from the color exchange space to a physical color space for the device.

10. The medium of claim 9, wherein the method includes clipping at least a portion of the sampled nodes inside the region of interest to an inflated gamut boundary to form clipped nodes.

11. The medium of claim 10, wherein the inflated gamut boundary is scaled and offset from the gamut boundary.

12. The medium of claim 10, wherein the method includes generating at least a portion of the table by using at least a portion of the clipped nodes.

13. The medium of claim 12, wherein the method includes converting data from the color exchange space to the physical color space for the device, by using the table and interpolation.

14. The medium of claim 12, wherein the method includes converting data by using output shapers.

15. The medium of claim 13, wherein the method includes converting data in an ICC profile.

16. A device, comprising:
an application specific integrated circuit (ASIC);
a memory, connected to the ASIC; and
program instructions storable in the memory and executable by the ASIC to:
sample a color exchange space, which includes a gamut boundary for an output device, to form sampled nodes;
define an inflated gamut boundary, based upon the gamut boundary; and
clip at least a portion of the sampled nodes to the inflated gamut boundary, to create clipped nodes.

17. The device of claim 16, including program instructions storable in the memory and executable by the processor to generate at least a portion of a table for converting data from the color exchange space to a physical color space for the output device, by using at least a portion of the clipped nodes.

18. The device of claim 17, including program instructions storable in the memory and executable by the processor to convert data from the color exchange space to the physical color space for the output device, by using the table.

19. A device, comprising:
a processor;
a memory, connected to the processor; and
means for converting data from a color exchange space to a physical color space for an output device so that data outside of a gamut boundary for the output device are mapped to device values on the gamut boundary.

20. The device of claim 19, wherein the means for converting the data includes a table for converting data from the color exchange space to the physical color space for the output device, wherein at least a portion of the table is generated by using sampled nodes clipped to an inflated boundary.
